(19) United States
(12) Patent Application Publication
(10) Pub. No.: US 2026/0188225 A1
(43) Pub. Date: Jul. 2, 2026

(54) Light Emitting Display Apparatus

(71) Applicant: LG Display Co., Ltd., Seoul (KR)

(72) Inventors: YoungChul Kwon, Paju-si (KR); Youngwan Ryu, Paju-si (KR)

(21) Appl. No.: 19/392,931

(22) Filed: Nov. 18, 2025

(30) Foreign Application Priority Data
Dec. 31, 2024 (KR) 10-2024-0202102

(51) Int. Cl. G09G 3/3233

(52) U.S. Cl. CPC G09G 3/3233; G09G 2300/043; G09G 2300/0819; G09G 2300/0842; G09G 2320/045

(57) ABSTRACT

A light emitting display apparatus presented herein includes a display panel including a plurality of subpixels. Each subpixel includes a light emitting device and a pixel circuit for driving the light emitting device. The pixel circuit includes a storage capacitor between a first node and a second node, a driving transistor including a gate electrode connected to the second node, a first electrode to which a driving power voltage is applied, and a second electrode connected to a third node, an aging transistor including a first electrode to which an aging voltage or a reference voltage is applied, a second electrode connected to the first node, and a gate electrode to which an aging control signal is applied, and transistors that control driving of the driving transistor. In an aging mode, the aging transistor applies the aging voltage to the first node to stabilize a voltage of the first node.

### CROSS-REFERENCE TO RELATED APPLICATION

The present application claims priority to Republic of Korea Patent Application No. 10-2024-0202102 filed on December 31, 2024, which is hereby incorporated by reference in its entirety.

### BACKGROUND

### Field

The present disclosure relates to a light emitting display apparatus.

### Description of Related Art

With the development of the information society, the demand for display apparatuses for displaying images has been increasing in various forms. For example, light emitting display apparatuses such as a liquid crystal display (LCD) apparatus, an organic light emitting display (OLED) apparatus, a micro light emitting diode (Micro LED) display apparatus, and a quantum dot display (QD) apparatus are being utilized.

The light emitting display apparatus may include a display panel configured to display an image, and a plurality of pixels as minimum units for displaying the image may be arranged in the display panel. Each of the pixels may include a pixel circuit, and the pixel circuit may include one or more transistors. When the off current of such transistors increases in a turn-off state, the pixel may emit light at an unintended timing, which may cause a problem such as a stain in the display panel.

### SUMMARY

A T-aging process is performed before a manufacturing process of the light emitting display apparatus or before image display, in which a bias based on a DC voltage is applied to a source and a drain of a transistor to trap electrons in a channel and thereby control the off current of the transistor. However, during the T-aging process, a voltage bias applied to some transistors of a pixel circuit may not be fixed and may fluctuate, so that the off current of the transistor cannot be controlled to a desired level, or damage and leakage current may occur due to high-voltage driving.

One or more embodiments of the present disclosure may provide a light emitting display apparatus capable of stably performing a T-aging process under optimal aging conditions.

Additional advantages and features of the present disclosure will be set forth in part in the description which follows and in part will become apparent to those having ordinary skill in the art upon examination of the following or may be learned from practice of the disclosure. The objectives and other advantages of the present disclosure may be realized and attained by the structure particularly pointed out in the written description and claims hereof as well as the appended drawings.

A light emitting display apparatus according to one or more embodiments of the present disclosure may include a display panel including a plurality of subpixels. Each of the plurality of subpixels may include a light emitting device and a pixel circuit configured to drive the light emitting device. The pixel circuit may include a storage capacitor connected between a first node and a second node, a driving transistor including a gate electrode connected to the second node, a first electrode to which a driving power voltage is applied, and a second electrode connected to a third node, an aging transistor including a first electrode to which an aging voltage or a reference voltage is applied, a second electrode connected to the first node, and a gate electrode to which an aging control signal is applied, and a plurality of transistors connected to the first node, the second node, the third node, or a fourth node connected to the light emitting device, and configured to control driving of the driving transistor. In an aging mode, while at least one of the plurality of transistors is being aged, the aging transistor may apply the aging voltage to the first node to stabilize a voltage of the first node.

According to one or more embodiments of the present disclosure, a light emitting display apparatus capable of stably performing a T-aging process under optimal aging conditions may be provided.

The light emitting display apparatus according to one or more embodiments of the present disclosure may stably perform a T-aging process under optimal aging conditions. Accordingly, a defect rate in a manufacturing process of the light emitting display apparatus may be reduced, thereby improving production yield and reliability. As a result, production energy may be reduced through process optimization, thereby realizing Environment, Social, and Governance (ESG) values.

The effects of the present disclosure are not limited to the aforesaid, but other effects not described herein will be clearly understood by those skilled in the art from the following descriptions.

The details of the present disclosure described in technical problem, technical solution, and advantageous effects do not specify essential features of claims, and thus, the scope of claims is not limited by the details described in detailed description of the present disclosure.

### BRIEF DESCRIPTION OF THE DRAWINGS

The accompanying drawings, which are included to provide a further understanding of the disclosure, are incorporated in and constitute a part of this disclosure, illustrate aspects and embodiments of the disclosure, and together with the description serve to explain the principles and examples of the present disclosure.

FIG. 1 illustrates a light emitting display apparatus according to one or more embodiments of the present disclosure.

FIG. 2 illustrates a circuit configuration of a subpixel according to one or more embodiments of the present disclosure.

FIG. 3 illustrates an operating state of a pixel circuit in an aging mode according to one or more embodiments of the present disclosure.

FIG. 4 illustrates an operating state of a pixel circuit in a driving mode according to one or more embodiments of the present disclosure.

FIG. 5 illustrates a layout of a pixel circuit according to one or more embodiments of the present disclosure.

FIG. 6 illustrates a circuit configuration of a subpixel according to one or more other embodiments of the present disclosure.

FIG. 7 illustrates a configuration of a display panel according to one or more other embodiments of the present disclosure.

FIG. 8 illustrates an operating state of a pixel circuit in an aging mode according to one or more other embodiments of the present disclosure.

FIG. 9 illustrates an operating state of a pixel circuit in a driving mode according to one or more other embodiments of the present disclosure.

FIG. 10 illustrates a layout of a pixel circuit according to one or more other embodiments of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction of thereof may be exaggerated for clarity, illustration, and/or convenience.

### DETAILED DESCRIPTION

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are examples and are provided so that this disclosure may be thorough and complete, to assist those skilled in the art to understand the inventive concepts without limiting the protected scope of the present disclosure.

Shapes (e.g., sizes, lengths, widths, heights, thicknesses, locations, radii, diameters, and areas), sizes, ratios, angles, numbers, and the like disclosed herein, including those illustrated in the drawings are merely examples, and thus, the present disclosure is not limited to the illustrated details. Any implementation described herein as an “example” is not necessarily to be construed as preferred or advantageous over other implementations. It is, however, noted that the relative dimensions of the components illustrated in the drawings are part of the present disclosure.

When the term “comprise,” “have,” “include,” “contain,” “constitute,” “made of,” “formed of,” or the like is used with respect to one or more elements, one or more other elements may be added unless a term such as “only” or the like is used. The terms used in the present disclosure are merely used in order to describe example embodiments and are not intended to limit the scope of the present disclosure. The terms of a singular form may include plural forms unless the context clearly indicates otherwise.

In construing an element, the element is construed as including an error region although there is no explicit description thereof.

In describing a positional relationship, for example, when the positional order is described as “on,” “above,” “below,” "beneath", and “next,” the case of no contact therebetween may be included, unless “just” or “direct” is used.

If it is mentioned that a first element is positioned “on” a second element, it does not mean that the first element is essentially positioned above the second element in the figure. The upper part and the lower part of an object concerned may be changed depending on the orientation of the object. Consequently, the case in which a first element is positioned “on” a second element includes the case in which the first element is positioned “below” the second element as well as the case in which the first element is positioned “above” the second element in the figure or in an actual configuration.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of the elements.

For the expression that an element is “connected,” “coupled,” “attached,” “adhered,” or the like to another element, the element may not only be directly connected, coupled, attached, adhered, or the like to another element, but also be indirectly connected, coupled, attached, adhered, or the like to another element with one or more intervening elements disposed or interposed between the elements, unless otherwise specified.

For the expression that an element is “contacts,” “overlaps,” or the like with another element, the element may not only directly contact, overlap, or the like with another element, but also indirectly contact, overlap, or the like with another element with one or more intervening elements disposed or interposed between the elements, unless otherwise specified.

The term “at least one” should be understood as including any and all combinations of one or more of the associated listed items. For example, “at least one among a first element, a second element and a third element” may include all combinations of two or more elements selected from the first, second and third elements as well as each element of the first, second and third elements.

Features of various embodiments of the present disclosure may be partially or entirety coupled to or combined with each other, may be technically associated with each other, and may be variously inter-operated, linked or driven together. The embodiments of the present disclosure may be implemented or carried out independently of each other or may be implemented or carried out together in a co-dependent or related relationship. In one or more aspects, the components of each apparatus according to various embodiments of the present disclosure are operatively coupled and configured.

In the following description, various example embodiments of the present disclosure are described in detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness, and thus, embodiments of the present disclosure are not limited to a scale, dimension, size, and thickness illustrated in the drawings.

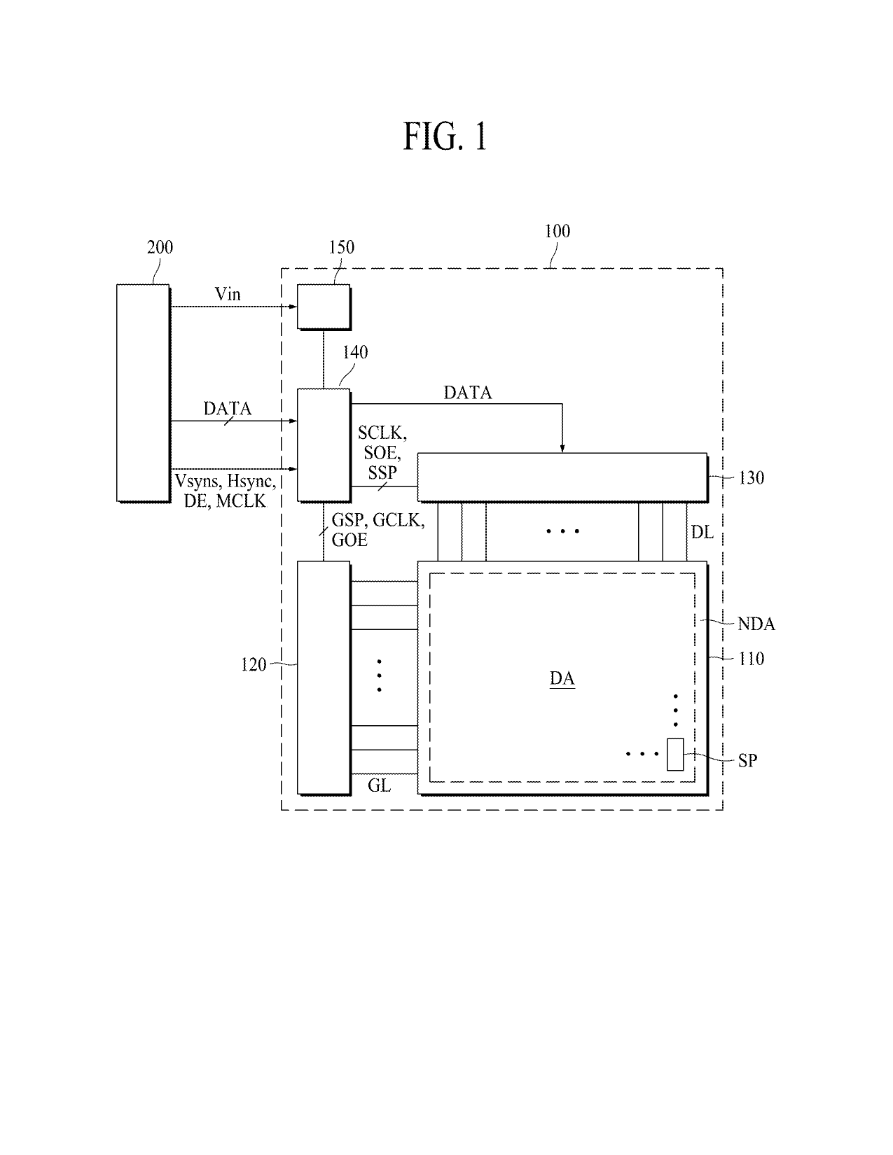

FIG. 1 illustrates a light emitting display apparatus according to one or more embodiments of the present disclosure.

A light emitting display apparatus 100 according to one or more embodiments of the present disclosure is implemented as an organic light emitting display apparatus, but may also be implemented as a liquid crystal display apparatus, a quantum dot lighting emitting diode display apparatus, or an electrophoretic display apparatus.

Referring to FIG. 1, the light emitting display apparatus 100 according to one or more embodiments of the present disclosure may include a display panel 110 in which a plurality of subpixels SP are arranged in a matrix form and a plurality of gate lines GL and data lines DL are connected, a gate driving circuit 120 configured to drive the plurality of gate lines GL, a data driving circuit 130 configured to supply data voltages through the plurality of data lines DL, a timing controller 140 configured to control the gate driving circuit 120 and the data driving circuit 130, and a power management IC (PMIC) 150.

The display panel 110 includes a display area DA and a non-display area NDA surrounding the display area DA. The display panel 110 includes pixels provided in the display area DA to display an image. Each of the pixels may include a plurality of subpixels SP. The structure of the subpixel SP may be variously changed according to the type of the light emitting display apparatus. For example, the subpixels SP may be formed in a top emission type, a bottom emission type, or a dual emission type according to the structure. The subpixels SP indicate a unit capable of forming a color filter of a specific type or capable of emitting a color of light by itself without forming a color filter. The subpixels SP may have one or more different light-emitting areas according to light-emitting characteristics. For example, the plurality of subpixels SP may be arranged in a stripe type or a quad type, but embodiments of the present disclosure are not limited thereto. The color type, arrangement type, arrangement order, and the like of the subpixels SP may be configured in various forms according to the light-emitting characteristics, lifespan of the apparatus, spec of the apparatus, and the like.

The display panel 110 may display an image based on a scan signal transmitted from the gate driving circuit 120 through the plurality of gate lines GL and a data signal transmitted from the data driving circuit 130 through the plurality of data lines DL. The plurality of gate lines GL and the plurality of data lines DL may be arranged to intersect each other. Each subpixel SP of the display panel 110 may be connected to one of the plurality of data lines DL and one of the plurality of gate lines GL.

The gate driving circuit 120 may be controlled by the timing controller 140 and may sequentially output scan signals to the plurality of gate lines GL to control the driving timing of the plurality of subpixels SP.

The gate driving circuit 120 may be located at one side or both sides of the display panel 110 depending on a driving method of the display panel 110. For example, the gate driving circuit 120 may be implemented in a bezel area of the display panel 110 in a gate driver in panel (GIP) manner or a tape automated bonding (TAB) manner, but the embodiments of the present disclosure are not limited thereto.

The data driving circuit 130 may receive image data DATA from the timing controller 140 and convert the received image data DATA into an analog data signal (or data voltage). The data driving circuit 130 may output the data voltage to each of the data lines DL in synchrony with the timing when a scan signal is applied through the gate lines GL, so that each subpixel SP connected to the data lines DL may display a light emission signal corresponding to the brightness of the data voltage.

The data driving circuit 130 may include one or more source driving integrated circuits D-IC. The source driving integrated circuits D-IC may be connected to the bonding pads of the display panel 110 by a TAB (Tape Automated Bonding) method or a COF (Chip On Film) method, or may be directly mounted on the display panel 110, but the embodiments of the present disclosure are not limited thereto.

The timing controller 140 may supply various control signals to the gate driving circuit 120 and the data driving circuit 130, and may control the operations of the gate driving circuit 120 and the data driving circuit 130. For example, the timing controller 140 may control the gate driving circuit 120 to output scan signals according to the timing implemented for each frame, and may transmit the digital image data DATA received from an external source to the data driving circuit 130.

The timing controller 140 may receive various timing signals, including image data DATA, a vertical synchronization signal Vsync, a horizontal synchronization signal Hsync, a data enable signal DE, and a main clock MCLK, from an external host system 200. For example, the host system 200 may be at least one of a television TV system, a set-top box, a navigation system, a personal computer PC, a home theater system, a mobile device, and a wearable device, but embodiments of the present disclosure are not limited thereto.

The timing controller 140 may generate control signals using various timing signals received from the host system 200, and may transmit these control signals to the gate driving circuit 120 and the data driving circuit 130.

The timing controller 140 may output various gate control signals, including a gate start pulse GSP, a gate clock GCLK, and a gate output enable signal GOE, to control the gate driving circuit 120. For example, the gate start pulse GSP may control the timing at which the gate driving circuit 120 begin operation. The gate clock GCLK is a clock signal input to the gate driving circuit 120 in common and may control the shift timing of the scan signal. The gate output enable signal GOE may control the output timing of the gate driving circuit 120.

The timing controller 140 may output various data control signals, including a source start pulse SSP, a source sampling clock SCLK, and a source output enable signal SOE, to control the data driving circuit 130. For example, the source start pulse SSP may control the timing at which the data driving circuit 130 begin data sampling. The source sampling clock SCLK may be a clock signal that controls the timing of data sampling in the data driving circuit 130. The source output enable signal SOE may control the output timing of the data driving circuit 130.

The light emitting display apparatus 100 according to one or more embodiments of the present disclosure may include a power management IC 150 configured to supply various voltages or currents to the display panel 110, the gate driving circuit 120, the data driving circuit 130, or to control various voltages or currents to be supplied.

The power management IC 150 may generate power necessary for driving the display panel 110, the gate driving circuit 120, and the data driving circuit 130 by adjusting a direct current input voltage Vin supplied from the host system 200.

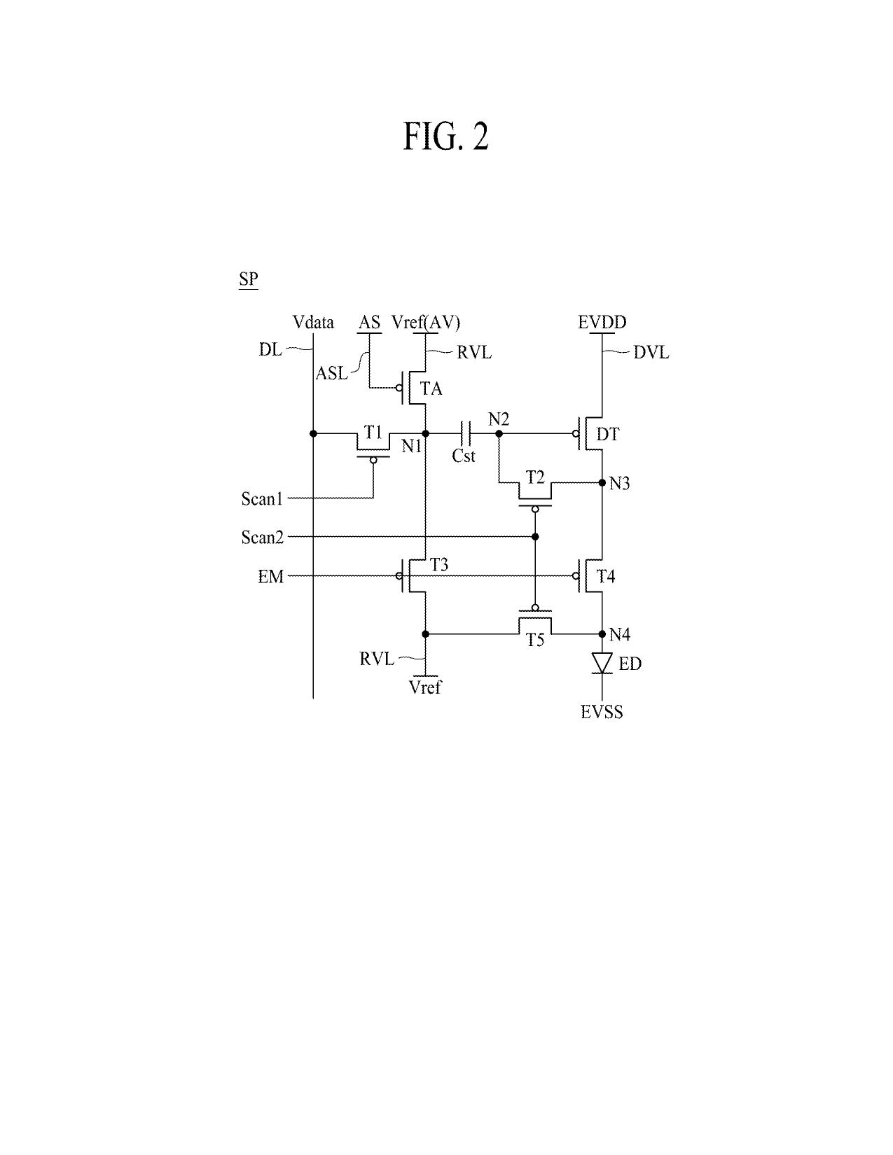

FIG. 2 illustrates a circuit configuration of a subpixel according to one or more embodiments of the present disclosure.

Referring to FIG. 2, the display panel 110 according to one or more embodiments of the present disclosure may include a plurality of subpixels SP constituting a unit pixel, and each subpixel SP may include a light emitting device ED and a pixel circuit configured to drive the light emitting device ED. The pixel circuit may include a storage capacitor Cst, a driving transistor DT, an aging transistor TA, and a plurality of transistors T1, T2, T3, T4, and T5. The pixel circuit according to one or more embodiments of the present disclosure may further include an internal compensation circuit capable of compensating for a threshold voltage of the driving transistor DT.

One or more transistors DT, TA, T1, T2, T3, T4, and T5 constituting the pixel circuit may be configured as thin film transistors (TFTs) having an N-type or P-type MOSFET (metal oxide semiconductor field effect transistor) structure, and may include an oxide TFT including an oxide semiconductor or an LTPS TFT including low temperature poly silicon (LTPS). For example, the one or more transistors DT, TA, T1, T2, T3, T4, and T5 may be three-electrode devices including a gate, a source, and a drain. The source electrode and the drain electrode are not fixed and may vary depending on a voltage applied to a gate electrode and a current direction. Accordingly, one of the source electrode and the drain electrode may be referred to as a first electrode, and the other may be referred to as a second electrode. The one or more transistors DT, TA, T1, T2, T3, T4, and T5 according to one or more embodiments of the present disclosure may be configured as P-type transistors, but the embodiments of the present disclosure are not limited thereto.

The one or more transistors DT, TA, T1, T2, T3, T4, and T5 may be controlled to be turned on or off by a scan signal (or a gate signal) applied to the gate electrode. The scan signal may swing between a gate-on voltage and a gate-off voltage.

The one or more transistors DT, TA, T1, T2, T3, T4, and T5 may be set such that a gate-on voltage is higher than a threshold voltage of the one or more transistors DT, TA, T1, T2, T3, T4, and T5, and a gate-off voltage is lower than the threshold voltage of the one or more transistors DT, TA, T1, T2, T3, T4, and T5. The one or more transistors DT, TA, T1, T2, T3, T4, and T5 may be turned on in response to the gate-on voltage or turned off in response to the gate-off voltage. For example, when the one or more transistors DT, TA, T1, T2, T3, T4, and T5 according to one or more embodiments of the present disclosure are P-type transistors, the gate-on voltage may be a gate low voltage VGL, and the gate-off voltage may be a gate high voltage VGH. Meanwhile, when the one or more transistors DT, TA, T1, T2, T3, T4, and T5 are N-type transistors, the gate-on voltage may be a gate high voltage VGH, and the gate-off voltage may be a gate low voltage VGL.

The light emitting device ED may include a pixel electrode (or a first electrode or an anode electrode) connected to the pixel circuit, a common electrode (or a second electrode or a cathode electrode) to which a common power voltage EVSS (or a second power voltage) is applied, and an emission layer disposed between the pixel electrode and the common electrode. The pixel electrode may be an independent electrode for each light emitting device ED, and the common electrode and the emission layer may be common layers shared by all of the light emitting devices ED. The light emitting device ED may generate light having a predetermined luminance in response to a driving current supplied from the pixel circuit.

The pixel circuit may receive power voltages such as a driving power voltage EVDD (or a first power voltage or a high-potential power voltage), a common power voltage EVSS (a second power voltage or a low-potential power voltage), and a reference power voltage Vref (a reference voltage or an initialization voltage). For example, the driving power voltage EVDD may be applied to the driving transistor DT through a driving voltage line DVL, the common power voltage EVSS may be applied to a second electrode of the light emitting device ED, and the reference power voltage Vref may be applied to a third transistor T3, a fifth transistor T5, and an aging transistor TA through a reference voltage line RVL.

The pixel circuit may receive signal voltages such as a first scan signal Scan 1, a second scan signal Scan 2, a light emitting control signal EM, a data voltage Vdata, and an aging control signal AS. For example, the first scan signal Scan 1, the second scan signal Scan 2, and the light emitting control signal EM may be supplied from the gate driving circuit 120 through a plurality of gate lines GL. The data voltage Vdata may be supplied from the data driving circuit 130 through a data line DL.

The aging control signal AS according to one or more embodiments of the present disclosure may be applied to the aging transistor TA through an aging control signal line ASL from the timing controller 140 or the data driving circuit 130. For example, the aging control signal AS may be directly supplied from the timing controller 140 or the data driving circuit 130 through the aging control signal line ASL, which is configured independently of lines to which a power voltage or a signal voltage is applied. Also, the aging control signal AS may be supplied from the data driving circuit 130 or the gate driving circuit 120 under control of the timing controller 140, but embodiments of the present disclosure are not limited thereto.

The driving transistor DT may be a driving device that controls a driving current flowing through the light emitting device ED according to a gate-to-source voltage Vgs. The driving transistor DT may include a gate electrode connected to a second node N2 that is connected to one side of a storage capacitor Cst, a first electrode to which the driving power voltage EVDD is applied through the driving power voltage line DVL, and a second electrode connected to a third node N3. For example, the second node N2 may be a gate node to which the gate electrode of the driving transistor DT is connected, the driving power voltage line DVL may be a source node to which a source electrode of the driving transistor DT is connected, and the third node N3 may be a drain node to which a drain electrode of the driving transistor DT is connected.

The first transistor T1 may be a switching device connected between a data line DL and a first node N1, and applies the data voltage Vdata to the first node N1 in response to the first scan signal Scan 1. The first transistor T1 may include a gate electrode to which the first scan signal Scan 1 is applied, a first electrode connected to the data line DL1, and a second electrode connected to the first node N1.

The storage capacitor Cst may be connected between the first node N1 and the second node N2 to store a threshold voltage of the driving transistor DT and to maintain a data voltage Vdata applied from the data line DL for a certain period of time.

The second transistor T2 may be a switching device connected between the second node N2 and the third node N3, and may electrically connect the second node N2 and the third node N3 in response to the second scan signal Scan 2. The second transistor T2 may include a gate electrode to which the second scan signal Scan 2 is applied, a first electrode connected to the second node N2, and a second electrode connected to the third node N3. For example, the second transistor T2 may allow a current to flow between the second and third nodes N2 and N3 so that the driving transistor DT may be diode-connected. When the driving transistor DT may be diode-connected, a potential of the second and third nodes N2 and N3 may correspond to a difference between a driving power voltage EVDD and a threshold voltage of the driving transistor DT, so that the threshold voltage of the driving transistor DT may be sampled. For example, the second transistor T2 may have a dual gate structure that may be robust against leakage current, but embodiments of the present disclosure are not limited thereto.

The third transistor T3 may be a switching device connected between the reference voltage line RVL and the first node N1, and may apply the reference voltage Vref to the first node N1 in response to the light emission control signal EM. The third transistor T3 may include a gate electrode to which the light emission control signal EM is applied, a first electrode connected to the first node N1, and a second electrode connected to the reference voltage line RVL.

The fourth transistor T4 may be a switching device connected between the third node N3 and a fourth node N4 connected to a first electrode (or an anode electrode) of the light emitting device ED, and may electrically connect the third node N3 and the fourth node N4 in response to the light emission control signal EM. The fourth transistor T4 may include a gate electrode to which the light emission control signal EM is applied, a first electrode connected to the third node N3, and a second electrode connected to the fourth node N4. For example, the fourth transistor T4 may allow a current to flow between the third and fourth nodes N3 and N4 so that a driving current generated by the driving transistor DT may be supplied to the first electrode of the light emitting device ED.

The fifth transistor T5 may be a switching device connected between the reference voltage line RVL and the fourth node N4, and may apply the reference voltage Vref to the fourth node N4 in response to the second scan signal Scan 2. The fifth transistor T5 may include a gate electrode to which the second scan signal Scan 2 is applied, a first electrode connected to the reference voltage line RVL, and a second electrode connected to the fourth node N4.

The aging transistor TA may be a switching device connected between the first node N1 and the reference voltage line RVL, and may apply the reference voltage Vref to the first node N1 in response to the aging control signal AS supplied through the aging control signal line ASL that is provided separately from lines to which a power voltage or a signal voltage is applied. The aging transistor TA may include a gate electrode to which the aging control signal AS is applied, a first electrode connected to the reference voltage line RVL, and a second electrode connected to the first node N1.

The aging transistor TA according to one or more embodiments of the present disclosure may apply an aging voltage through the reference voltage line RVL to the first node N1 in an aging mode in which at least one of the plurality of transistors T1, T2, T3, T4, and T5 may be aged, so as to stabilize a voltage of the first node N1. For example, the aging voltage may have a voltage level set to maintain the voltage of the first node N1 at a fixed voltage in the aging mode.

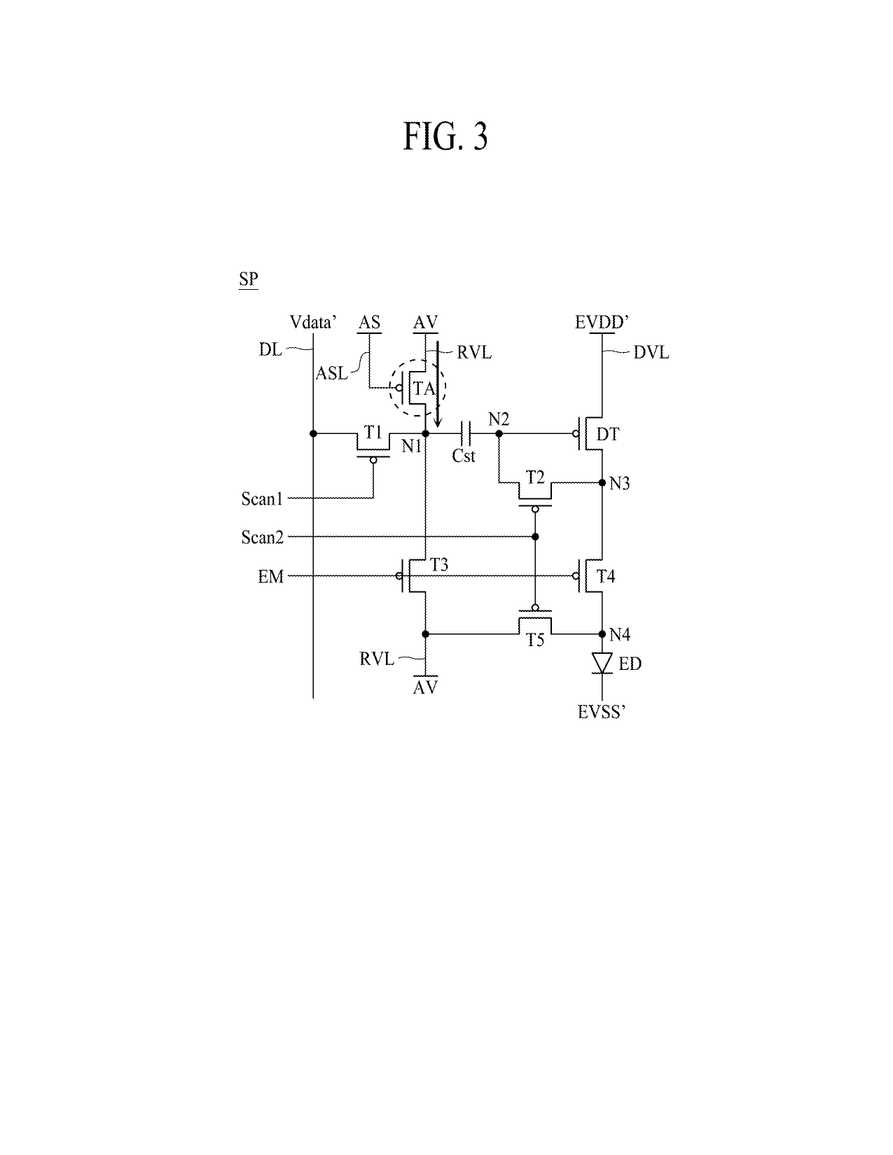

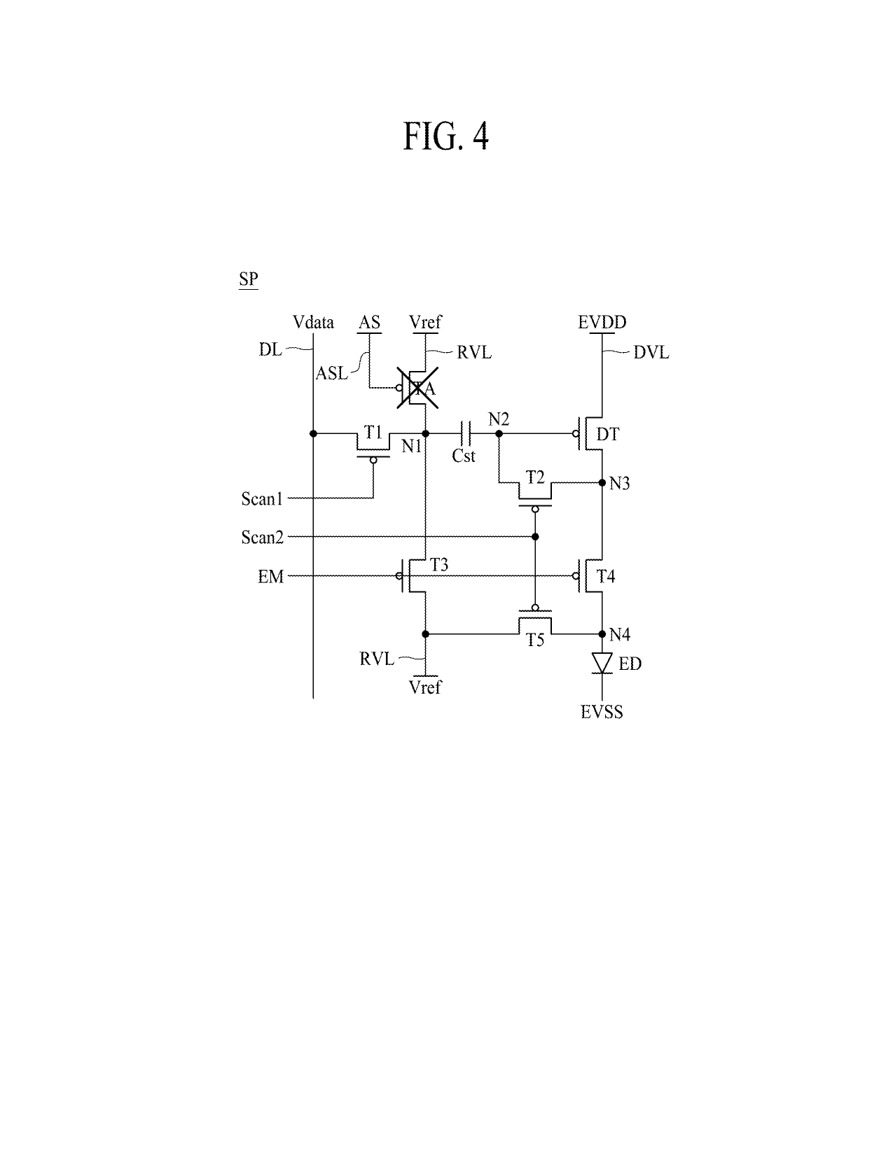

FIG. 3 illustrates an operating state of a pixel circuit in an aging mode according to one or more embodiments of the present disclosure. FIG. 4 illustrates an operating state of a pixel circuit in a driving mode according to one or more embodiments of the present disclosure.

Referring to FIGS. 3 and 4, the light emitting display apparatus 100 according to one or more embodiments of the present disclosure may perform the aging mode, which is separate from the driving mode for driving the light emitting device ED, by aging at least one of the driving transistor DT and the plurality of transistors T1, T2, T3, T4, and T5 included in the pixel circuit of each subpixel SP, so that an off current of the transistors may be reduced and characteristics of the transistors may be improved.

The aging mode may improve bright spots, dark spots, and stains that appear at low gray levels by performing transistor aging (T-aging) before a manufacturing process or image display of the light emitting display apparatus 100. For example, aging of the transistors may be performed to improve characteristics of the transistors, and may be carried out by applying a high voltage, a low voltage, or a swing between the high and low voltages while gates of the transistors are turned off, or by driving a pixel circuit in the same manner as under a normal driving condition. For example, when aging is performed under the same condition as the normal driving condition of the pixel circuit, input voltages may be applied as voltages optimized for aging, which are different from those applied under the actual normal driving condition.

In the aging mode, an aging driving voltage used for the pixel circuit may be set such that an aging driving power voltage EVDD′ applied through the driving power voltage line DVL may be set to a first voltage (for example, −15 V) or a second voltage (for example, 20 V) within a range of −15 V to 20 V, so that a specific condition can be established for transistors included in the pixel circuit. An aging data voltage Vdata′ applied through the data line DL may be set to a first voltage (for example, 0 V) or a second voltage (for example, 20 V) within a range of 0 V to 20 V, and an aging common power voltage EVSS′ applied to a cathode of the light emitting device ED may be set to a first voltage (for example, −10 V) or a second voltage (for example, 0 V) within a range of −10 V to 0 V. In addition, the first scan signal Scan 1 may have a gate-on voltage VGL and a gate-off voltage VGH set within a range of −9 V to 24 V, the second scan signal Scan 2 may have the gate-on voltage VGL and the gate-off voltage VGH set within a range of −13 V to 20 V, and the light emission control signal EM may have the gate-on voltage VGL and the gate-off voltage VGH set within a range of −18 V to 20 V, but embodiments of the present disclosure are not limited thereto.

Accordingly, in the aging mode, the aging driving power voltage EVDD′, the aging data voltage Vdata′, the aging common power voltage EVSS′, the scan signals Scan 1 and Scan 2, the light emission control signal EM, and the aging voltage AV may be applied to all transistors of the pixel circuit so that stress may be applied to the driving transistor DT and the plurality of transistors T1, T2, T3, T4, and T5. At this time, since an aging driving voltage is not directly applied to the first node N1, the second node N2, and the third node N3 of the pixel circuit, the plurality of transistors T1, T2, T3, T4, and T5 may be electrically floated in a turned-off state, and a voltage of the first node N1 may fluctuate without being fixed to the aging data voltage Vdata′. Accordingly, a stress condition of the first and third transistors T1 and T3 may not be controlled to a desired level.

Accordingly, the pixel circuit according to one or more embodiments of the present disclosure may further include the aging transistor TA connected to the first node N1, and may apply the aging voltage AV to the first node N1 in the aging mode so that a voltage of the first node N1 may be stabilized by maintaining the voltage of the first node N1 at a fixed voltage.

Referring to FIG. 3, the aging transistor TA according to one or more embodiments of the present disclosure may be connected to the reference voltage line RVL. The aging transistor TA may apply the aging voltage AV to the first node N1 in response to the aging control signal AS applied through the aging control signal line ASL. For example, the aging voltage may have a voltage level set to maintain the voltage of the first node N1 at a fixed voltage in the aging mode. To this end, in the aging mode, the reference voltage line RVL may be supplied with the aging voltage AV having a voltage level higher or lower than the reference voltage Vref. For example, the reference voltage Vref may be set to 2.8 V, but embodiments of the present disclosure are not limited thereto.

According to one or more embodiments of the present disclosure, the aging voltage AV applied through the reference voltage line RVL may be set to a first voltage (for example, −15 V) or a second voltage (for example, 15 V) within a range of −15 V to 15 V. When the aging voltage AV is applied to the first node N1 by the aging transistor TA, the first node N1 may not be electrically floated even when the first transistor T1 is turned off, and the aging voltage AV may be maintained as a fixed voltage so that a voltage of the first node N1 may be stabilized. Accordingly, a voltage of the second node N2, which is at the opposite side of the storage capacitor Cst, may also be stabilized. In addition, as voltages of the first node N1 and the second node N2 are stabilized, a voltage of the third node N3 connected to the second transistor T2 configured with a dual gate structure that is robust against leakage current may also be stabilized.

Referring to FIG. 4, the aging transistor TA according to one or more embodiments of the present disclosure may be switched to a turned-off state in response to the aging control signal AS applied as a gate-off voltage VGH in the driving mode for driving the light emitting device ED. The aging transistor TA may remain in the turned-off state during the driving mode. Accordingly, in the driving mode, the reference voltage Vref may not be applied to the first node N1. According to one or more other embodiments of the present disclosure, in the driving mode, the aging control signal AS may be synchronized with the light emission control signal EM, and the aging transistor TA may be turned on together with the third transistor T3 so that the reference voltage Vref may be applied to the first node N1, but embodiments of the present disclosure are not limited thereto. For example, the aging transistor TA may initialize a voltage of the first node N1 in the driving mode.

In the driving mode of a light emitting display apparatus 100 according to one or more embodiments of the present disclosure, the driving power voltage EVDD may be set to 13 V, the data voltage Vdata may be adjusted according to a gray level of image data within a range of 0 V to 6 V, the common power voltage EVSS may be set to 0 V, and the reference voltage Vref may be set to 2.8 V. In addition, the first scan signal Scan 1, the second scan signal Scan 2, and the light emission control signal EM may have the gate-on voltage VGL and the gate-off voltage VGH set within a range of −9 V to 14.5 V, but embodiments of the present disclosure are not limited thereto.

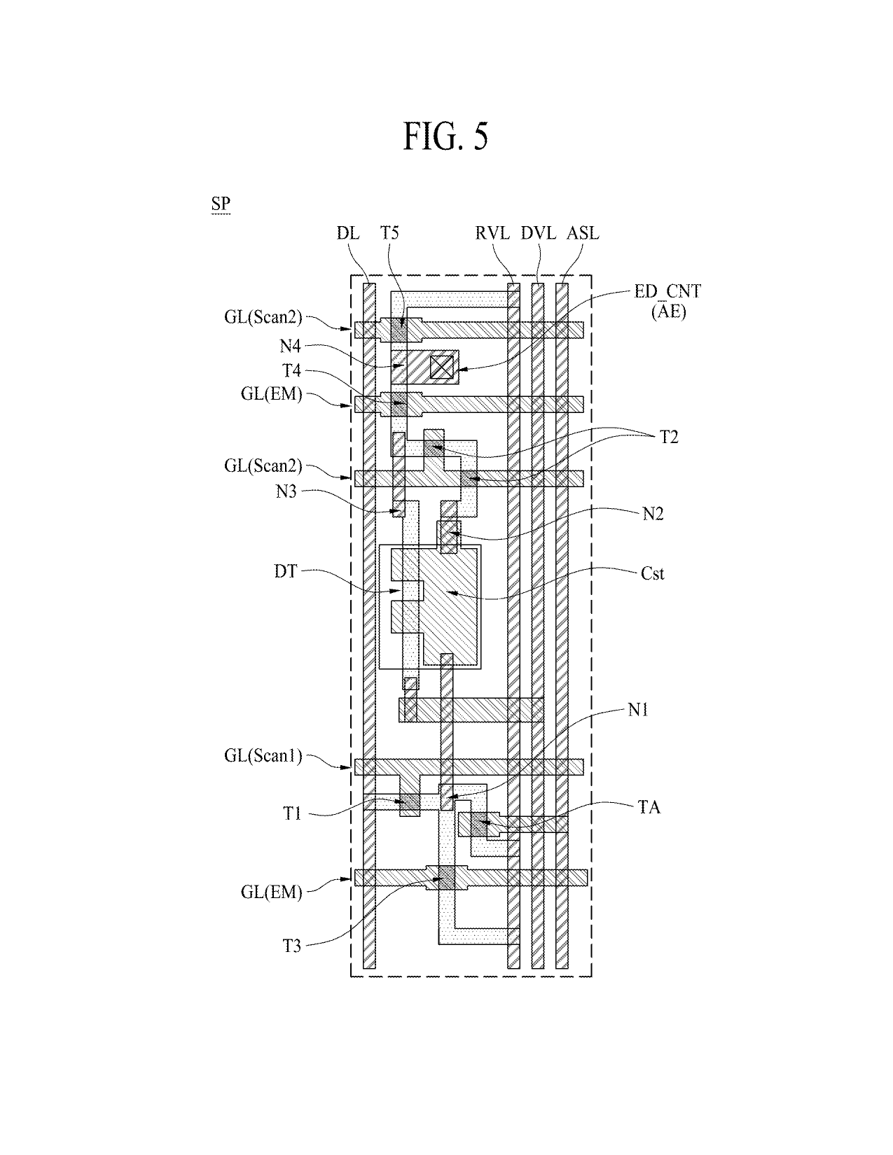

FIG. 5 illustrates a layout of a pixel circuit according to one or more embodiments of the present disclosure.

Referring to FIG. 5, the pixel circuit according to one or more embodiments of the present disclosure may include the plurality of gate lines GL extending in a first direction (or X-axis direction), and the data line DL, the reference voltage line RVL, the driving power voltage line DVL, and the aging control signal line ASL extending in a second direction (or Y-axis direction) that intersects the first direction.

The pixel circuit may include the driving transistor DT, the storage capacitor Cst, the plurality of transistors T1, T2, T3, T4, and T5, and the aging transistor TA.

The driving transistor DT may be disposed at a central portion of the pixel circuit. For example, the driving transistor DT may be disposed at the center of an arrangement region of the pixel circuit with respect to the second direction, but embodiments of the present disclosure are not limited thereto. The storage capacitor Cst may be disposed adjacent to the driving transistor DT.

Below the driving transistor DT, the first transistor T1, the third transistor T3, and the aging transistor TA may be disposed. In addition, above the driving transistor DT, the second transistor T2, the fourth transistor T4, and the fifth transistor T5 may be disposed. For example, the driving transistor DT may be disposed between the second transistor T2 and the first transistor T1 along the second direction.

The aging transistor TA according to one or more embodiments of the present disclosure may be disposed between the first transistor T1 and the third transistor T3 along the second direction (or Y-axis direction) on a plane. One side of the aging transistor TA may be connected to the reference voltage line RVL. In addition, a gate electrode of the aging transistor TA may be connected to the aging control signal line ASL extending parallel to the reference voltage line RVL, and may extend in the first direction from the aging control signal line ASL. For example, the aging control signal line ASL may be commonly connected to the plurality of subpixels SP arranged in the second direction (or Y-axis direction).

The first transistor T1 may have one side connected to the data line DL, and the third transistor T3 may have one side connected to the reference voltage line RVL that extends parallel to the data line DL. The first transistor T1, the third transistor T3, and the aging transistor TA may be disposed between the data line DL and the reference voltage line RVL along the first direction (or X-axis direction). The first transistor T1, the third transistor T3, and the aging transistor TA may each have the other side commonly connected to the first node N1.

The second transistor T2 may be disposed adjacent to the driving transistor DT. A gate electrode of the second transistor T2 may transmit the second scan signal Scan 2 and may have a dual gate structure including a portion of the gate line GL extending in the first direction and a portion protruding in the second direction from the gate line GL.

The fourth transistor T4 and the fifth transistor T5 may be disposed parallel to each other in the second direction (or Y-axis direction) on a plane. For example, the fourth transistor T4 may be disposed below in the second direction, and the fifth transistor T5 may be disposed above in the second direction. In addition, a contact portion ED_CNT connected to the light emitting device ED may be disposed between the fourth transistor T4 and the fifth transistor T5. The contact portion ED_CNT may be connected to a pixel electrode AE of the light emitting device ED.

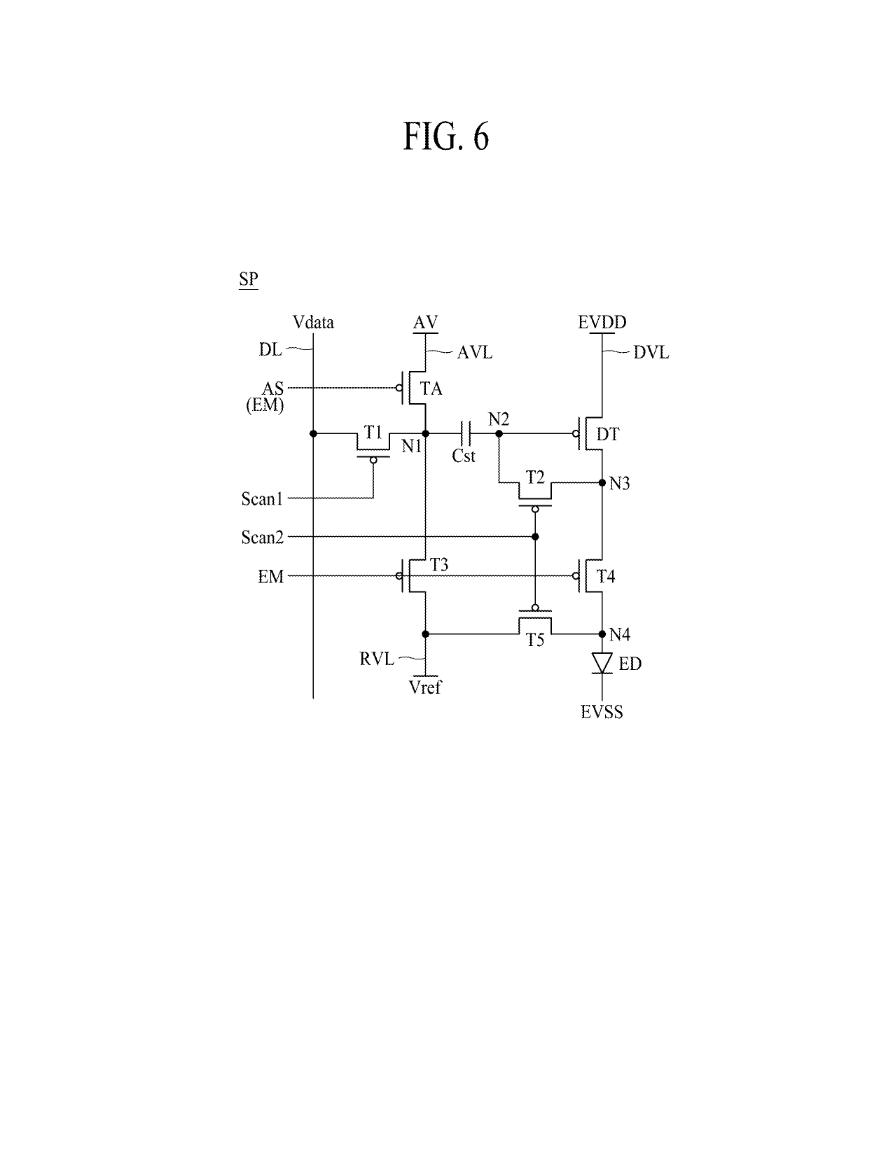

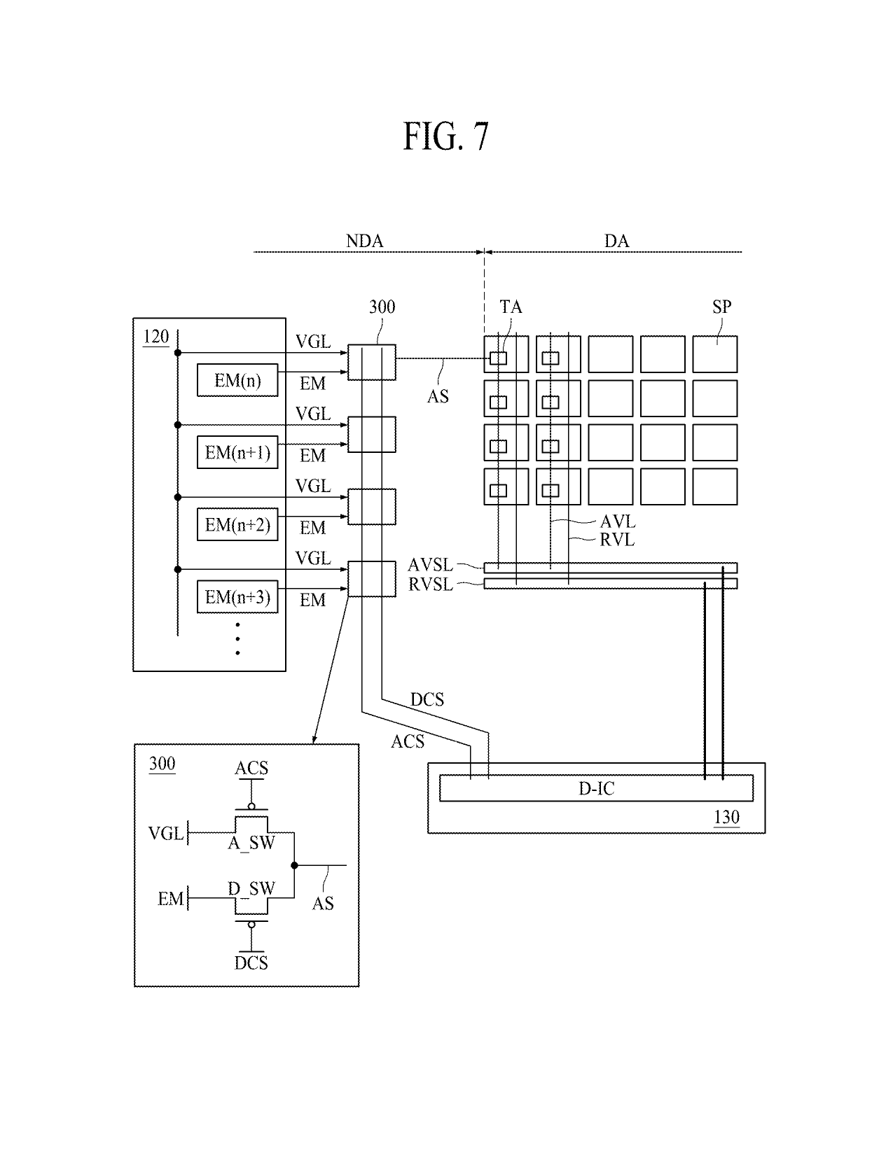

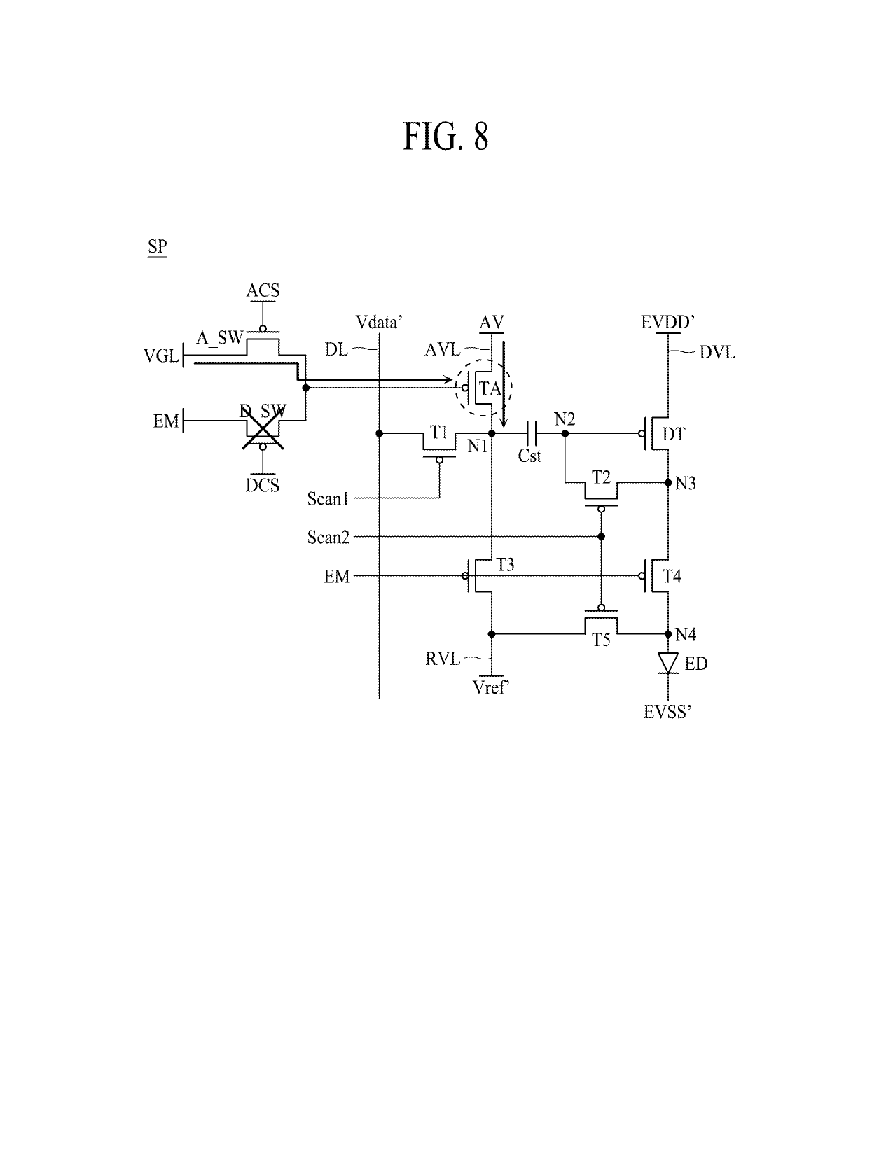

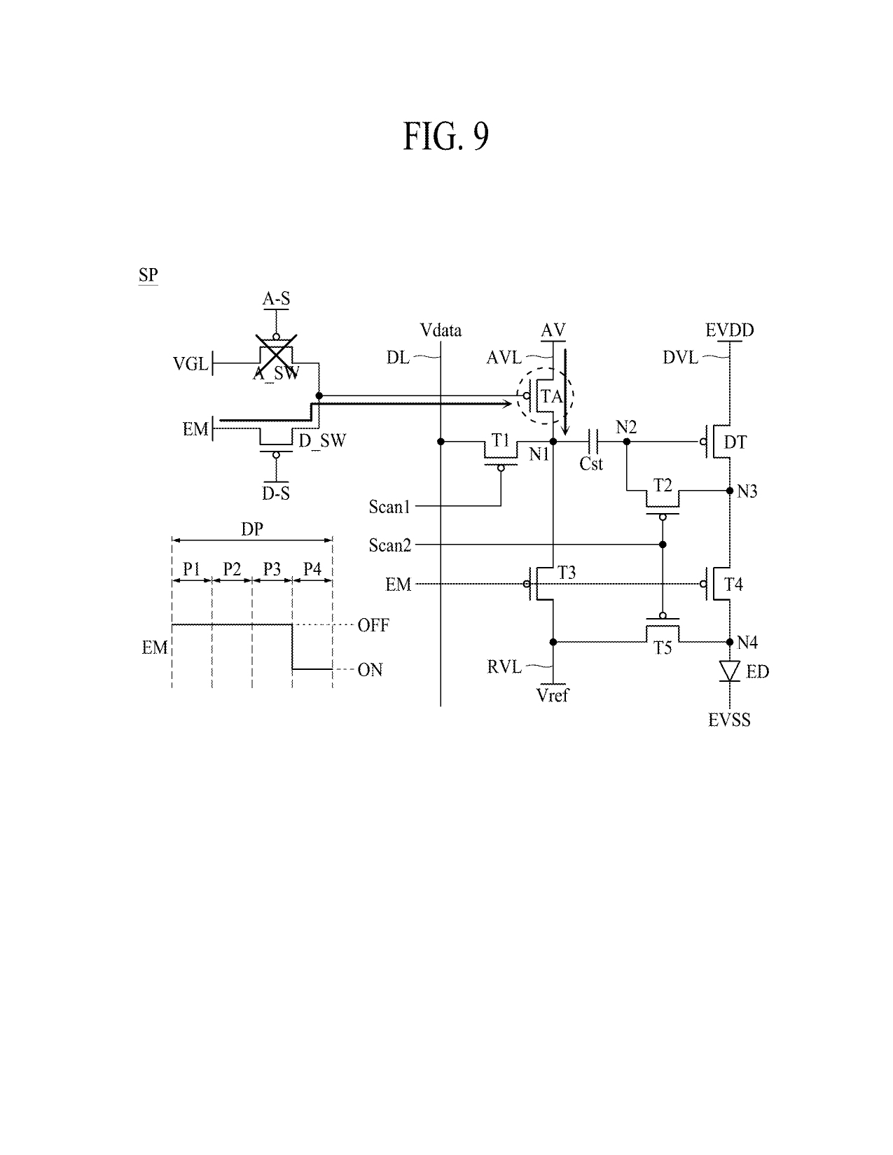

FIG. 6 illustrates a circuit configuration of a subpixel according to one or more other embodiments of the present disclosure. FIG. 7 illustrates a configuration of a display panel according to one or more other embodiments of the present disclosure. FIG. 8 illustrates an operating state of a pixel circuit in an aging mode according to one or more other embodiments of the present disclosure. FIG. 9 illustrates an operating state of a pixel circuit in a driving mode according to one or more other embodiments of the present disclosure. FIGS. 6 to 9 illustrate modifications of the aging transistor configuration in the light emitting display apparatus described with reference to FIGS. 1 to 5. In the following description, the same reference numerals are used for the same components except for the modified configuration, and redundant descriptions thereof are omitted or briefly described.

Referring to FIGS. 6 to 9, the aging transistor TA according to one or more other embodiments of the present disclosure may be a switching device connected between the first node N1 and the aging voltage line AVL configured independently of the plurality of power voltage lines EVDD and RVL, and may apply the aging voltage AV to the first node N1 in response to the aging control signal AS supplied through an aging control signal line as a part of the plurality of gate lines GL. The aging transistor TA may include a gate electrode to which the aging control signal AS is applied, a first electrode connected to the aging voltage line AVL, and a second electrode connected to the first node N1.

The aging control signal AS according to one or more other embodiments of the present disclosure may be applied to the aging transistor TA through one of the plurality of gate lines GL from the gate driving circuit 120. The aging control signal AS may be configured to share at least one signal among the plurality of gate lines GL. For example, the aging control signal AS may be configured to share the light emission control signal EM. The aging control signal AS may be directly supplied from the gate driving circuit 120, or may be supplied from the gate driving circuit 120 under control of the timing controller 140, but embodiments of the present disclosure are not limited thereto. For example, the aging control signal line may be commonly connected to the plurality of subpixels SP arranged in the first direction (or X-axis direction).

The aging transistor TA according to one or more other embodiments of the present disclosure may apply an aging voltage to the first node N1 through the aging voltage line AVL provided separately from lines to which a power voltage or a signal voltage is applied, in the aging mode in which at least one of the plurality of transistors T1, T2, T3, T4, and T5 may be aged, so as to stabilize a voltage of the first node N1. For example, the aging voltage may have a voltage level set to maintain the voltage of the first node N1 at a fixed voltage in the aging mode.

Referring to FIG. 7, the display panel 110 according to one or more other embodiments of the present disclosure may include the display area DA in which the plurality of subpixels SP are arranged, and the non-display area NDA around the display area DA.

The aging voltage AV and the reference voltage Vref supplied from a source driver integrated circuit D-IC of the data driving circuit 130 may be applied to the pixel circuit of each subpixel SP. For example, the aging voltage AV may be applied to the aging transistor TA.

The non-display area NDA of the display panel 110 may further include a reference voltage shorting line RVSL connected to the reference voltage line RVL and an aging voltage shorting line AVSL connected to the aging voltage line AVL.

The reference voltage Vref output from the data driving circuit 130 may be applied to the reference voltage shorting line RVSL and may be supplied to each pixel circuit through the reference voltage lines RVL distributed from the reference voltage shorting line RVSL. In addition, the aging voltage AV output from the data driving circuit 130 may be applied to the aging voltage shorting line AVSL and may be supplied to the aging transistors TA of the respective pixel circuits through the aging voltage lines AVL distributed from the aging voltage shorting line AVSL.

The aging control signal AS supplied from the gate driving circuit 120 disposed in the non-display area NDA may be applied to the aging transistor TA of each subpixel SP.

The gate driving circuit 120 may output the first scan signal Scan 1, the second scan signal Scan 2, the light emission control signal EM, and the aging control signal AS. An aging control signal switching unit 300 may be further provided between the gate driving circuit 120 and the display area DA. For example, the aging control signal switching unit 300 may selectively supply either the gate-on voltage VGL or the light emission control signal EM as the aging control signal to the aging transistor TA.

The gate driving circuit 120 may output the gate-on voltage VGL and the light emission control signal EM. The gate-on voltage VGL and the light emission control signal EM may be supplied to the aging control signal switching unit 300.

The aging control signal switching unit 300 may supply either the gate-on voltage VGL or the light emission control signal EM to the aging transistor TA according to control signals DCS and ACS applied from the timing controller 140 or the data driving circuit 130. For example, the aging control signal switching unit 300 may include an aging selection switch A_SW and a driving selection switch D_SW. In the aging mode, the first control signal ACS may be applied as the gate-on voltage VGL, and the second control signal DCS may be applied as the gate-off voltage VGH. In addition, in the driving mode, the first control signal ACS may be applied as the gate-off voltage VGH, and the second control signal DCS may be applied as the gate-on voltage VGL.

The aging control signal switching unit 300 may deliver the aging control signal AS having the gate-on voltage VGL to the aging transistor TA in the aging mode, and may deliver the aging control signal AS having the light emission control signal EM to the aging transistor TA in the driving mode.

Referring to FIG. 8, the aging transistor TA according to one or more other embodiments of the present disclosure may be connected to the aging voltage line AVL configured separately from the reference voltage line RVL. The aging transistor TA may apply the aging voltage AV to the first node N1 in response to the gate-on voltage VGL applied by the aging control signal switching unit 300. In the aging mode, the aging control signal may be applied as the gate-on voltage VGL. The aging voltage AV may have a voltage level set to maintain the voltage of the first node N1 at a fixed voltage in the aging mode.

According to one or more other embodiments of the present disclosure, the aging voltage AV may have a voltage level different from the aging reference voltage Vref′ applied through the reference voltage line RVL in the aging mode. The aging voltage AV applied through the aging voltage line AVL may be set to a first voltage (for example, 0 V) or a second voltage (for example, 20 V) within a range of 0 V to 20 V. In addition, the aging reference voltage Vref′ applied through the reference voltage line RVL may be set to a first voltage (for example, −15 V) or a second voltage (for example, 15 V) within a range of −15 V to 15 V.

When the aging voltage AV is applied to the first node N1 by the aging transistor TA, the first node N1 may not be electrically floated even when the first transistor T1 is in a turned-off state, and the aging voltage AV may be maintained as a fixed voltage so that a voltage of the first node N1 may be stabilized. Accordingly, a voltage of the second node N2, which is at the opposite side of the storage capacitor Cst, may also be stabilized. In addition, as voltages of the first node N1 and the second node N2 are stabilized, a voltage of the third node N3 connected to the second transistor T2 configured with a dual gate structure that is robust against leakage current may also be stabilized.

Referring to FIG. 9, the aging transistor TA according to one or more other embodiments of the present disclosure may apply the aging voltage AV to the first node N1 in response to the light emission control signal EM applied by the aging control signal switching unit 300 in the driving mode for driving the light emitting device ED. In the driving mode, the aging voltage AV may have a voltage level equal to the reference voltage Vref.

In the driving mode, the pixel circuit may be driven by being divided into an initialization period P1, a sampling period P2, a holding period P3, and an emission period P4. The light emission control signal EM may be applied as the gate-off voltage VGH during the initialization period P1, the sampling period P2, and the holding period P3, and may be applied as the gate-on voltage VGL during the emission period P4. Accordingly, the aging transistor TA may be turned on during the emission period P4 of the driving mode to apply the aging voltage AV corresponding to the reference voltage Vref to the first node N1.

In the driving mode of the light emitting display apparatus 100 according to one or more other embodiments of the present disclosure, the driving power voltage EVDD may be set to 13 V, the data voltage Vdata may be adjusted according to a gray level of image data within a range of 0 V to 6 V, the common power voltage EVSS may be set to 0 V, and both the reference voltage Vref and the aging voltage AV may be set to 2.8 V. In addition, the first scan signal Scan 1, the second scan signal Scan 2, and the light emission control signal EM may have the gate-on voltage VGL and the gate-off voltage VGH set within a range of −9 V to 14.5 V, but embodiments of the present disclosure are not limited thereto.

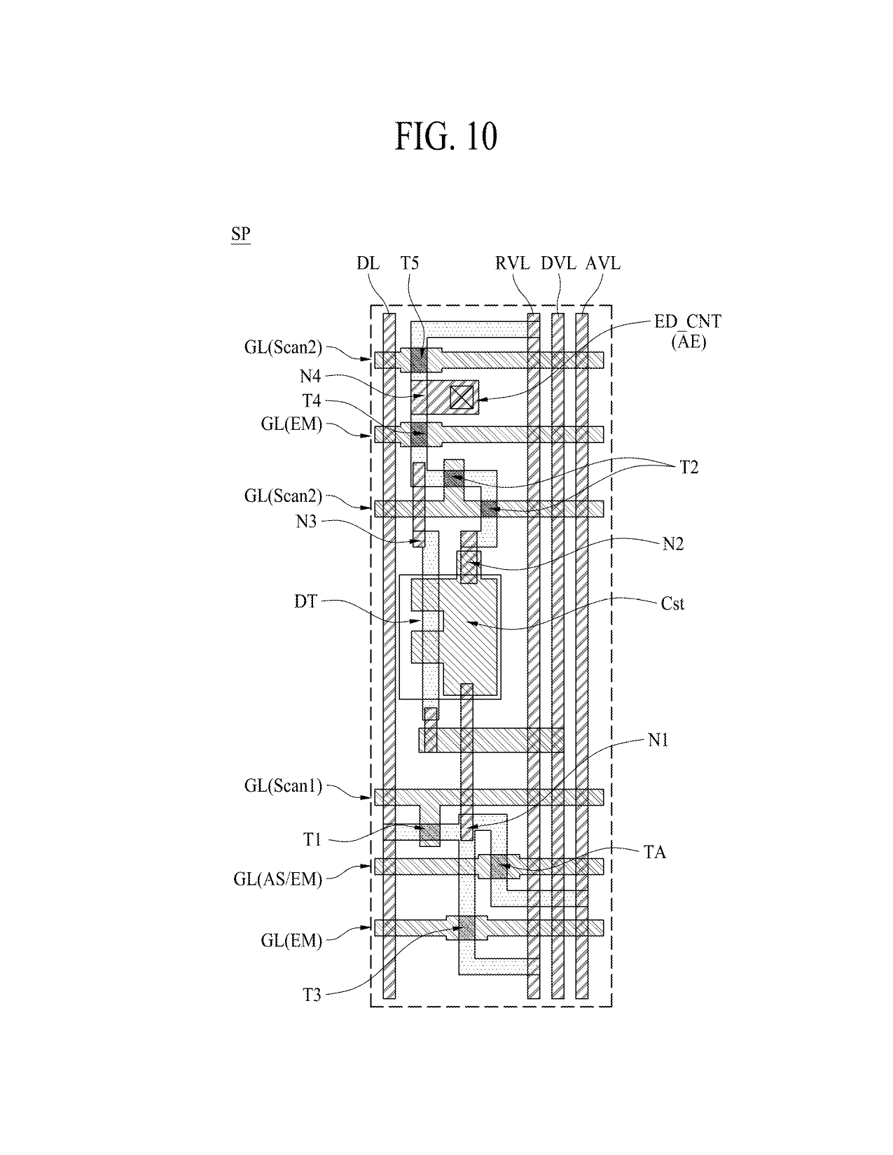

FIG. 10 illustrates a layout of a pixel circuit according to one or more other embodiments of the present disclosure. FIG. 10 illustrates a modification of the configuration of the aging transistor TA in the layout of the pixel circuit described with reference to FIG. 5. In the following description, the same reference numerals are used for the same components except for the modified configuration, and redundant descriptions thereof are omitted or briefly described.

Referring to FIG. 10, the pixel circuit according to one or more other embodiments of the present disclosure may include the plurality of gate lines GL extending in the first direction (or X-axis direction), and the data line DL, the reference voltage line RVL, the driving power voltage line DVL, and the aging voltage line AVL extending in the second direction (or Y-axis direction) that intersects the first direction.

The pixel circuit may include the driving transistor DT, the storage capacitor Cst, the plurality of transistors T1, T2, T3, T4, and T5, and the aging transistor TA.

The aging transistor TA according to one or more other embodiments of the present disclosure may be disposed between the first transistor T1 and the third transistor T3 along the second direction (or Y-axis direction) on a plane. One side of the aging transistor TA may be connected to the aging voltage line AVL. In addition, a gate electrode of the aging transistor TA may be configured as a part of the gate line GL to which an aging control signal is applied. For example, the aging control signal may be commonly connected to the plurality of subpixels SP arranged in the first direction (or X-axis direction) through the gate line GL extending in the first direction.

A light emitting display apparatus according to one or more embodiments of the present disclosure will be described below.

A light emitting display apparatus according to one or more embodiments of the present disclosure may include a display panel including a plurality of subpixels. Each of the plurality of subpixels may include a light emitting device and a pixel circuit configured to drive the light emitting device. The pixel circuit may include a storage capacitor connected between a first node and a second node, a driving transistor including a gate electrode connected to the second node, a first electrode to which a driving power voltage is applied, and a second electrode connected to a third node, an aging transistor including a first electrode to which an aging voltage or a reference voltage is applied, a second electrode connected to the first node, and a gate electrode to which an aging control signal is applied, and a plurality of transistors connected to the first node, the second node, the third node, or a fourth node connected to the light emitting device, and configured to control driving of the driving transistor. In an aging mode, while at least one of the plurality of transistors is being aged, the aging transistor may apply the aging voltage to the first node to stabilize a voltage of the first node.

According to one or more embodiments of the present disclosure, in a driving mode for driving the light emitting device, the aging transistor may apply the reference voltage to the first node to initialize a voltage of the first node.

According to one or more embodiments of the present disclosure, the aging voltage may have a voltage level higher or lower than the reference voltage.

According to one or more embodiments of the present disclosure, the display panel may include a plurality of gate lines extending in a first direction and a plurality of power voltage lines extending in a second direction crossing the first direction, and an aging control signal may be applied to the aging transistor through an aging control signal line extending parallel to the plurality of power voltage lines or the plurality of gate lines.

According to one or more embodiments of the present disclosure, the aging control signal line may be commonly connected to a plurality of subpixels arranged in the second direction or to a plurality of subpixels arranged in the first direction.

According to one or more embodiments of the present disclosure, the aging control signal line may be configured independently of the plurality of power voltage lines or configured to share a signal with at least one of the plurality of gate lines.

According to one or more embodiments of the present disclosure, the aging voltage may be applied to the aging transistor through at least one of the plurality of power voltage lines or through an aging voltage line configured independently of the plurality of power voltage lines.

According to one or more embodiments of the present disclosure, the first electrode of the aging transistor may be connected to a reference voltage line among the plurality of power voltage lines, the reference voltage line being configured to deliver a reference voltage in a driving mode.

According to one or more embodiments of the present disclosure, the reference voltage line may deliver the aging voltage in the aging mode and may deliver the reference voltage in the driving mode.

According to one or more embodiments of the present disclosure, the first electrode of the aging transistor may be connected to the aging voltage line, the aging voltage line may deliver the aging voltage in the aging mode and may deliver the reference voltage in the driving mode, and the aging voltage may have a voltage level different from a power voltage applied through the plurality of power voltage lines in the aging mode.

According to one or more embodiments of the present disclosure, the plurality of transistors may include a first transistor connected between a data line and the first node and configured to apply a data voltage of the data line to the first node through a gate electrode to which a first scan signal is applied, a second transistor connected between the second node and the third node and configured to electrically connect the second node and the third node through a gate electrode to which a second scan signal is applied, a third transistor connected between a reference voltage line and the first node and configured to apply a reference voltage of the reference voltage line to the first node through a gate electrode to which a light emitting control signal is applied, a fourth transistor connected between the third node and the fourth node and configured to electrically connect the third node and the fourth node through a gate electrode to which the light emitting control signal is applied, and a fifth transistor connected between the reference voltage line and the fourth node and configured to apply the reference voltage of the reference voltage line to the fourth node through a gate electrode to which the second scan signal is applied.

According to one or more embodiments of the present disclosure, the first to fifth transistors may be configured as P-type transistors.

According to one or more embodiments of the present disclosure, the second transistor may be configured as a transistor having a dual-gate structure.

According to one or more embodiments of the present disclosure, the first scan signal, the second scan signal, and the light emitting control signal may be respectively applied through a plurality of gate lines extending in a first direction, and the aging transistor may be disposed, in a plane, between the first transistor and the third transistor along a second direction crossing the first direction.

According to one or more embodiments of the present disclosure, the first transistor may be connected to the data line extending in the second direction, the third transistor may be connected to the reference voltage line extending parallel to the data line, and the first transistor, the third transistor, and the aging transistor may be disposed between the data line and the reference voltage line along the first direction.

According to one or more embodiments of the present disclosure, the fourth transistor and the fifth transistor may be disposed in parallel in a plane along the second direction, and the driving transistor may be disposed between the fourth transistor and the first transistor along the second direction.

According to one or more embodiments of the present disclosure, the aging transistor may be connected to the reference voltage line, and the gate electrode of the aging transistor may be connected to an aging control signal line extending parallel to the reference voltage line and may be configured to extend from the aging control signal line in the first direction.

According to one or more embodiments of the present disclosure, the aging transistor may be connected to an aging voltage line extending parallel to the reference voltage line, and the gate electrode of the aging transistor may be configured as a part of an aging control signal line extending parallel to the plurality of gate lines.

According to one or more embodiments of the present disclosure, the aging control signal line may deliver the aging control signal in the aging mode and may deliver the light emitting control signal in the driving mode.

According to one or more embodiments of the present disclosure, the display panel may include a display area in which the plurality of subpixels are arranged and a non-display area surrounding the display area, and the light emitting display apparatus may further include a gate driving circuit disposed in the non-display area and configured to output the first scan signal, the second scan signal, the light emitting control signal, and the aging control signal, and an aging control signal switching portion disposed between the gate driving circuit and the display area and configured to selectively supply the aging control signal or the light emitting control signal to the aging transistor.

The above-described feature, structure, and effect of the present disclosure are included in at least one embodiment of the present disclosure, but are not limited to only one embodiment. Furthermore, the feature, structure, and effect described in at least one embodiment of the present disclosure may be implemented through combination or modification of other embodiments by those skilled in the art. Therefore, content associated with the combination and modification should be construed as being within the scope of the present disclosure.

It will be apparent to those skilled in the art that various modifications and variations can be made in the present disclosure without departing from the spirit or scope of the present disclosure. Thus, it is intended that the present disclosure covers the modifications and variations of this disclosure provided they come within the scope of the appended claims and their equivalents.

What is claimed is:

1. A light emitting display apparatus, comprising:
a display panel including a plurality of subpixels,
wherein each of the plurality of subpixels includes a light emitting device and a pixel circuit configured to drive the light emitting device, the pixel circuit comprising:
a storage capacitor connected between a first node and a second node;
a driving transistor including a gate electrode connected to the second node, a first electrode to which a driving power voltage is applied, and a second electrode connected to a third node;
an aging transistor including a first electrode to which an aging voltage or a reference voltage is applied, a second electrode connected to the first node, and a gate electrode to which an aging control signal is applied; and
a plurality of transistors connected to the first node, the second node, the third node, or a fourth node connected to the light emitting device, the plurality of transistors configured to control driving of the driving transistor,
wherein, in an aging mode of the light emitting display apparatus, while at least one of the plurality of transistors is being aged, the aging transistor applies the aging voltage to the first node to stabilize a voltage of the first node.

2. The light emitting display apparatus of claim 1, wherein, in a driving mode of the light emitting display apparatus for driving the light emitting device, the aging transistor applies the reference voltage to the first node to initialize a voltage of the first node.

3. The light emitting display apparatus of claim 1, wherein the aging voltage has a voltage level higher or lower than the reference voltage.

4. The light emitting display apparatus of claim 1, wherein the display panel comprises a plurality of gate lines extending in a first direction and a plurality of power voltage lines extending in a second direction crossing the first direction, and wherein the aging control signal is applied to the aging transistor through an aging control signal line extending parallel to the plurality of power voltage lines or the plurality of gate lines.

5. The light emitting display apparatus of claim 4, wherein the aging control signal line is commonly connected to a plurality of subpixels arranged in the second direction or to a plurality of subpixels arranged in the first direction.

6. The light emitting display apparatus of claim 5, wherein the aging control signal line is configured independently of the plurality of power voltage lines or configured to share a signal with at least one of the plurality of gate lines.

7. The light emitting display apparatus of claim 4, wherein the aging voltage is applied to the aging transistor through at least one of the plurality of power voltage lines or through an aging voltage line configured independently of the plurality of power voltage lines.

8. The light emitting display apparatus of claim 7, wherein the first electrode of the aging transistor is connected to a reference voltage line among the plurality of power voltage lines, and wherein the reference voltage line is configured to deliver a reference voltage in a driving mode of the light emitting display apparatus.

9. The light emitting display apparatus of claim 8, wherein the reference voltage line delivers the aging voltage in the aging mode, and wherein the reference voltage line delivers the reference voltage in the driving mode.

10. The light emitting display apparatus of claim 7, wherein the first electrode of the aging transistor is connected to the aging voltage line,
wherein the aging voltage line delivers the aging voltage in the aging mode,
wherein the aging voltage line delivers the reference voltage in a driving mode of the light emitting display apparatus, and
wherein the aging voltage has a voltage level different from a power voltage applied through the plurality of power voltage lines in the aging mode.

11. The light emitting display apparatus of claim 1, wherein the plurality of transistors comprise:
a first transistor connected between a data line and the first node, the first transistor configured to apply a data voltage of the data line to the first node through a gate electrode of the first transistor to which a first scan signal is applied;
a second transistor connected between the second node and the third node, the second transistor configured to electrically connect the second node and the third node through a gate electrode of the second transistor to which a second scan signal is applied;
a third transistor connected between a reference voltage line and the first node, the third transistor configured to apply a reference voltage of the reference voltage line to the first node through a gate electrode of the third transistor to which a light emitting control signal is applied;
a fourth transistor connected between the third node and the fourth node, the fourth transistor configured to electrically connect the third node and the fourth node through a gate electrode of the fourth transistor to which the light emitting control signal is applied; and
a fifth transistor connected between the reference voltage line and the fourth node, the fifth transistor configured to apply the reference voltage of the reference voltage line to the fourth node through a gate electrode of the fifth transistor to which the second scan signal is applied.

12. The light emitting display apparatus of claim 11, wherein the first transistor, the second transistor, the third transistor, the fourth transistor and the fifth transistor are configured as P-type transistors.

13. The light emitting display apparatus of claim 11, wherein the second transistor is configured as a transistor having a dual-gate structure.

14. The light emitting display apparatus of claim 11, wherein the first scan signal, the second scan signal, and the light emitting control signal are respectively applied through a plurality of gate lines extending in a first direction, and wherein the aging transistor is disposed, in a plane, between the first transistor and the third transistor along a second direction crossing the first direction.

15. The light emitting display apparatus of claim 14, wherein the first transistor is connected to the data line extending in the second direction,
wherein the third transistor is connected to the reference voltage line extending parallel to the data line, and
wherein the first transistor, the third transistor, and the aging transistor are disposed between the data line and the reference voltage line along the first direction.

16. The light emitting display apparatus of claim 14, wherein the fourth transistor and the fifth transistor are disposed in parallel in a plane along the second direction, and wherein the driving transistor is disposed between the fourth transistor and the first transistor along the second direction.

17. The light emitting display apparatus of claim 15, wherein the aging transistor is connected to the reference voltage line,
wherein the gate electrode of the aging transistor is connected to an aging control signal line extending parallel to the reference voltage line, and
wherein the gate electrode is configured to extend from the aging control signal line in the first direction.

18. The light emitting display apparatus of claim 15, wherein the aging transistor is connected to an aging voltage line extending parallel to the reference voltage line, and
wherein the gate electrode of the aging transistor is configured as a part of an aging control signal line extending parallel to the plurality of gate lines.

19. The light emitting display apparatus of claim 18, wherein the aging control signal line delivers the aging control signal in the aging mode, and wherein the aging control signal line delivers the light emitting control signal in a driving mode of the light emitting display apparatus.

20. The light emitting display apparatus of claim 19, wherein the display panel comprises a display area in which the plurality of subpixels are arranged and a non-display area surrounding the display area, and
wherein the light emitting display apparatus further comprises:
a gate driving circuit disposed in the non-display area, the gate driving circuit configured to output the first scan signal, the second scan signal, the light emitting control signal, and the aging control signal; and
an aging control signal switching portion disposed between the gate driving circuit and the display area, the aging control signal switching portion configured to selectively supply the aging control signal or the light emitting control signal to the aging transistor.
